(19) United States
(12) Patent Application Publication
(10) Pub. No.: US 2024/0297116 A1
(43) Pub. Date: Sep. 5, 2024

(54) INTEGRATED PACKAGING DEVICE AND FABRICATION METHODS THEREOF

(71) Applicant: Qorvo US, Inc., Greensboro, NC (US)

(72) Inventors: Anthony Chiu, Collin, TX (US); Terry Joe Hon, Saint Paul, TX (US)

(21) Appl. No.: 18/442,937

(22) Filed: Feb. 15, 2024

Related U.S. Application Data
(60) Provisional application No. 63/487,858, filed on Mar. 1, 2023.

(51) Int. Cl. H01L 23/528; H01L 21/60; H01L 21/768; H01L 23/14

(52) U.S. Cl. CPC H01L 23/5283; H01L 21/60; H01L 21/7688; H01L 23/142; H01L 23/5286

(57) ABSTRACT

An integrated packaging device is provided. The integrated device includes a base layer, an insulating layer over and in contact with the base layer, and a conductive layer over and in contact with the insulating layer. The conductive layer includes a conductive pattern. The integrated device also includes an opening extending from the conductive layer to the base layer. The conductive pattern surrounds the opening.

### RELATED APPLICATIONS

This application claims priority to U.S. Provisional Patent Application No. 63/487,858 filed Mar. 1, 2023, which is incorporated by reference herein in its entirety.

### FIELD OF THE INVENTION

This disclosure relates to the packaging of integrated circuits. In particular, this disclosure relates to an integrated packaging device and fabrication methods to form the integrated packaging device.

### BACKGROUND

Packaging is an essential part for semiconductor devices, especially those operating at high frequency and high power. Packaging can affect the functionality of the enclosed semiconductor devices (chips), as well as the power, performance, and cost of the final product. A package is a container that holds a chip/semiconductor die and provides pathways for electrical connection between the chip and an external circuitry. A package can be made of metal, plastic, glass, and/or ceramic casing. The package also protects the chip against mechanical impact, chemical contamination, and light exposure. In addition, the package helps dissipate heat produced by the chip so as to maintain normal operations of the chip.

However, the packages, especially for chips operating at high power and high frequency, have limitations. For example, ceramic materials have been widely used as a packaging material for their high thermal conductivities (160 W/m-K for aluminum nitride), but have limitations such as high dielectric constants (e.g., Dk=10), high cost, and long fabrication time (e.g., at least six months), making them unsuitable for prototype product development. Organic laminate substrates with an embedded coin (e.g., with thermal conductivity of 390 W/m-K) have low substrate dielectric constants (e.g., Dk=2˜4) and have shorter fabrication time, but are limited to containing semiconductor dies of relatively small sizes. Eutectic die attach (a process involving the heating of the substrate to effect die bonding) is often not possible for organic laminate substrates. Thus, it is important to design a package with improved heat dissipation, low cost, low dielectric constant, improved eutectic die attachment, and improved size adaption.

### SUMMARY

Aspects of the present disclosure include an integrated packaging device. The integrated packaging device includes a base layer, an insulating layer over and in contact with the base layer, and a conductive layer over and in contact with the insulating layer. The conductive layer includes a conductive pattern. The integrated packaging device also includes an opening extending from the conductive layer to the base layer. The conductive pattern surrounds the opening.

In some embodiments, a bottom surface of the opening is between a top surface and a bottom surface of the base layer.

In some embodiments, the insulating layer comprises epoxy or polytetrafluoroethylene (PTFE).

In some embodiments, the opening is configured for placing a circuit chip. In some embodiments, a depth of the opening is at least a sum of a thickness of the insulating layer, a thickness of the conductive layer, a thickness of the circuit chip, and a thickness of a bonding over the conductive layer.

In some embodiments, a thickness of the base layer is between about 200 μm and about 1000 μm, a thickness of the insulating layer is between about 200 μm and about 300 μm, and a thickness of the conductive layer is between about 10 μm and about 50 μm.

In some embodiments, the opening comprises a rectangular portion and at least one protruding portion in connection with a corner of the rectangular portion.

In some embodiments, the opening comprises four protruding portions each in connection with a corner of the rectangular portion.

In some embodiments, the base layer and the conductive layer each comprises copper.

In some embodiments, the integrated packaging device further includes a plurality of conductive vias connecting a ground line of the conductive pattern and the base layer.

In some embodiments, the integrated packaging device further includes a mask layer surrounding the opening and separating an inner portion and an outer portion of the conductive pattern. In some embodiments, a plurality of conductive leads in contact with the outer portion of the conductive pattern.

Aspects of the present disclosure includes a method for forming an integrated packaging device. The method includes forming a stack structure having a base layer, a layer of an insulating material over the base layer, and a conductive material layer over the layer of the insulating material. The method also includes patterning the conductive material layer, and the layer of the insulating material to form a base conductive layer having a first opening, and patterning the stack structure to form a second opening from the first opening. The second opening is smaller than the first opening and extending from a top surface of the base conductive layer into the base layer.

In some embodiments, the method further includes, prior to the patterning of the conductive material layer, patterning the stack structure to form a plurality of holes in an area corresponding to a ground line in the base conductive layer. The plurality of holes extend from the conductive material layer to the base layer. The method also includes forming a plurality of conductive vias each in a respective one of the plurality of holes.

In some embodiments, the plurality of conductive vias are formed by electroplating or electroless plating.

In some embodiments, in the conductive vias include copper.

In some embodiments, the forming of the stack structure includes, prior to the forming of the stack structure, patterning an insulating material layer to form the layer of the insulating material that has a third opening matching the first opening. In some embodiments, the forming of the stack structure also includes laminating the base layer, the layer of the insulating material, and the conductive material layer to form the stack structure.

In some embodiments, the laminating of the base layer, the layer of the insulating material, and the conductive material layer includes applying at least one of heat and pressure on the base layer, the layer of the insulating material, and the conductive material layer such that the layer of the insulating material is attached to each of the conductive material layer and the base layer.

In some embodiments, the patterning of the insulating material layer comprises laser cutting.

In some embodiments, the patterning of the stack structure to form the second opening from the first opening comprises machining the stack structure in the first opening to expose the base layer. The opening has a rectangular portion and at least one protruding portion in connection with a corner of the rectangular portion.

In some embodiments, the opening is formed by machining the layer of the insulating material and the base layer to form the rectangular portion, and machining or drilling the corner of the rectangular portion to form the at least one protruding portion.

In some embodiments, the method further includes forming a mask layer surrounding the second opening and dividing the base conductive layer into an inner portion and an outer portion, plating a gold layer covering the inner and outer portions of the base conductive layer to form a conductive layer, and welding the one or more conductive leads onto the gold layer covering the outer portion of the base conductive layer.

### BRIEF DESCRIPTION OF THE DRAWINGS

FIG. 1A illustrates an exemplary integrated packaging device, according to some embodiments of the present disclosure.

FIG. 1B illustrates a top view of the integrated packaging device, according to some embodiments of the present disclosure.

FIG. 1C illustrates a cross-sectional view of the integrated packaging device along an A-A′ direction illustrated in FIG. 1B, according to some embodiments of the present disclosure.

FIG. 1D illustrates a top view of a pocket area, according to some embodiments of the present disclosure.

FIG. 1E illustrates a cross-sectional view of the pocket area, according to some embodiments of the present disclosure.

FIG. 2 illustrates a flowchart of a method for forming an integrated packaging device, according to some embodiments of the present disclosure.

FIGS. 3A-3I illustrate an exemplary process for forming an integrated packaging device, according to some embodiments of the present disclosure.

FIGS. 4A-4G illustrate part of another exemplary process for forming an integrated packaging device, according to some embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

Reference will now be made in greater detail to various embodiments of the subject matter of the present disclosure, some embodiments of which are illustrated in the accompanying drawings.

As used herein, the term “about” refers to a given amount of value that may vary based on the particular technology node associated with the semiconductor device. Based on a particular technology node, the term “about” can refer to a given amount of value that varies, for example, within 10-30% of the value (e.g., ±10%, ±20%, or ±20% of that value, or ±30%).

Chips operating at high power and high frequency can be assembled in a package that has desirably high heat dissipation, low cost, low dielectric constant, improved eutectic die attachment, and improved size adaption. For example, an existing package for a high-power and high-frequency chip can include a copper coin embedded in a multi-layer structure of a plurality of copper layers and a plurality of resin layers. The copper coin is placed to be in contact with a chip, and conducts heat from one side (e.g., in contact with the chip) to another (e.g., in contact with a cooling media such as a heatsink). The copper coin is often closely surrounded by the resin/copper layers, and its ability of heat dissipation is limited. Also, the package can be undesirably thick, with the thickness often around 1 mm. Another existing package can include an assembly structure that has a copper base, an adhesive layer attached/glued to the copper base, and a circuit board attached/glued to the copper base via the adhesive layer. A chip is placed in the middle of the circuit board. This package can have a thickness less than 1 mm, and the contact between the chip and the surrounding air is maximized to improve heat dissipation. However, the alignment of different parts in the assembly can be challenging. Also, such package is costly, and the manufacturing of the package requires parts from different suppliers, making it a less sustainable option for packaging.

Embodiments of the present disclosure provide an integrated packaging device of low cost, improved heat dissipation, improved eutectic die attachment, and improved size adaption. The integrated packaging device can be formed from fabricating a one-piece structure, instead of an assembly of different parts. Such fabrication can reduce the burden of alignment, while maintaining/improving desirable heat dissipation. The integrated packaging device can be flexibly designed to fit chips of different sizes with improved eutectic die attachment. Because the manufacturing of the integrated packaging device does not require assembly fabricated parts from different suppliers, the cost of manufacturing can be reduced, and the fabrication process can be simplified.

The integrated packaging device includes a base layer, an insulating layer over the base layer, and a conductive layer over the insulating layer. The conductive layer includes a conductive pattern that functions as a circuit. In some embodiments, the conductive pattern is referred to as a top metal layer/pattern. For example, the integrated packaging device includes one or more conductive vias in contact with the conductive layer (or ground lines of the conductive pattern) and the base layer to form ground in the circuit. The insulating layer can function as a glue layer that attaches the base layer and the conductive layer directly. The integrated packaging device may also include an opening surrounded by the conductive pattern. The opening extends from the top surface of the conductive layer to the base layer. The depth of the opening can be designed to match an impedance between the chip and the conductive pattern by adjusting the length of the bonding wire. This matching impedance is further extended between this conductive pattern and the mother board on which the integrated packaging device is mounted. The opening includes a rectangle and one or more protruding portions each at a corner of the rectangle. The opening minimizes the movement of the chip, and allows the chip to be placed desirably close to the edge of the opening (e.g., to the circuit/conductive pattern).

The integrated packaging device can be fabricated from a stack structure. In some embodiments, the stack structure includes a base layer, an insulating material layer, and a conductive material stacked together. The integrated packaging device can be formed by forming the conductive vias in the insulating material layer and the conductive material layer, and patterning the conductive material layer, the insulating material layer, and the base layer. In some embodiments, the insulating material layer is pre-patterned to form the insulating layer before the formation of the stack structure. The insulating layer may then be laminated with a base layer and a conductive material layer to form the stack structure. The conductive vias may then be formed in the insulating layer and the conductive material layer. The conductive material layer and the base layer may then be patterned. In some embodiments, the insulating material layer is patterned using laser cutting. The base layer is patterned (e.g., to form the opening for holding the chip) by machining and/or drilling.

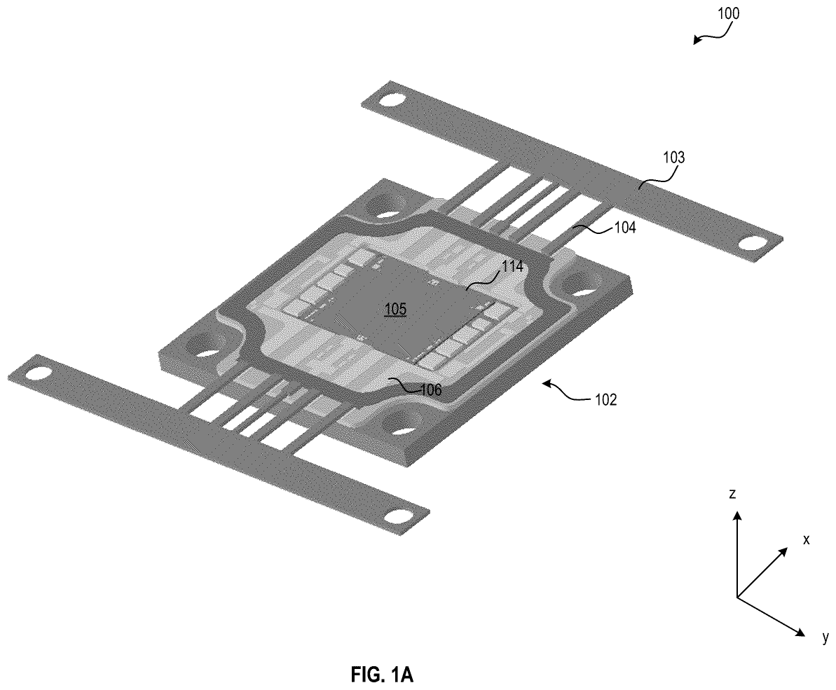

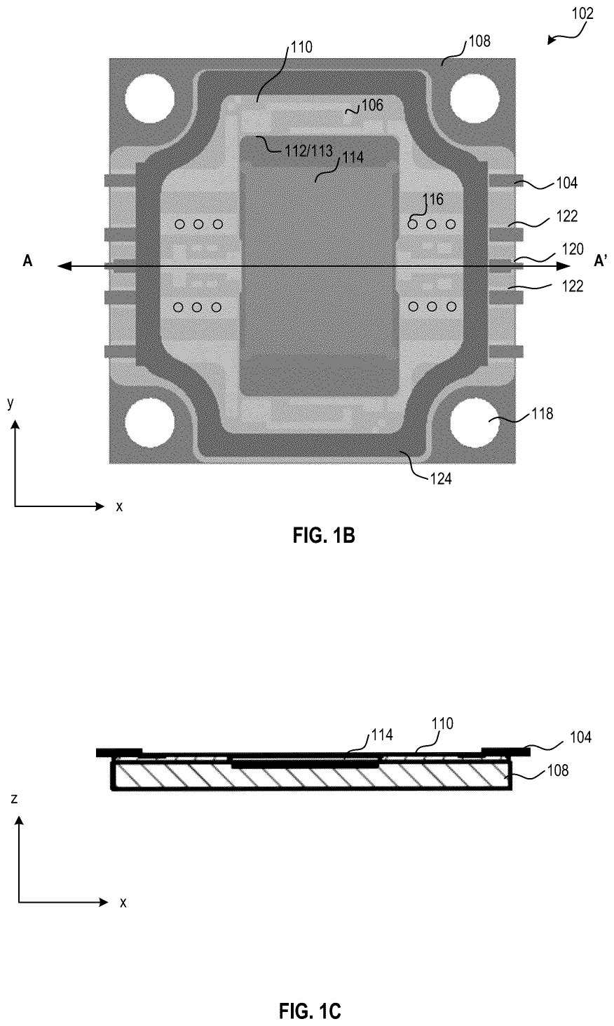

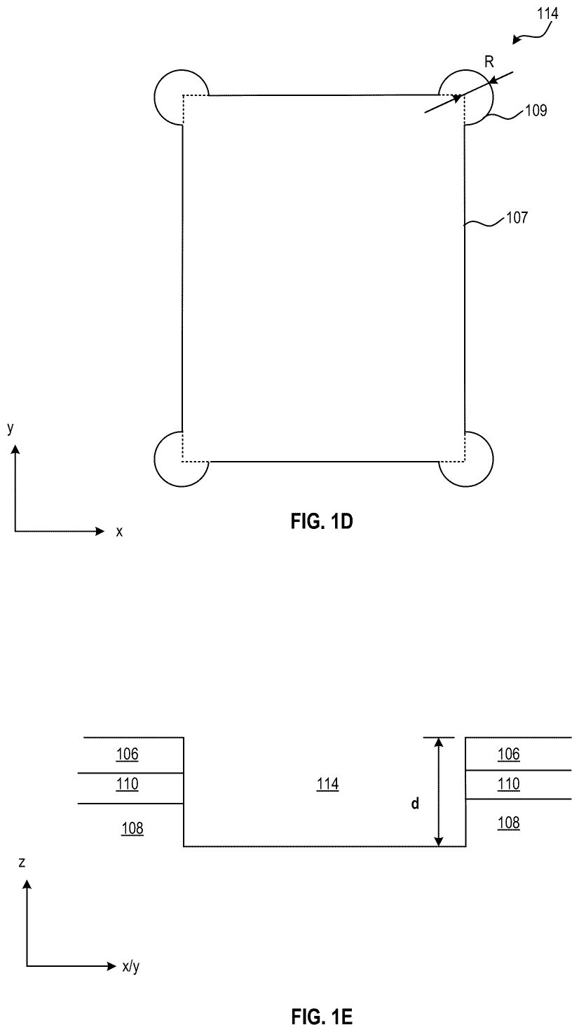

FIG. 1A illustrates an exemplary integrated packaging device 100, according to some embodiments of the present disclosure. Integrated packaging device 100 may include a chip holder 102, a plurality of metal leads 104 attached to chip holder 102, and one or more connecting structures 103 attached to metal leads 104. A chip 105, e.g., one operating at high power and high frequency, may be placed in chip holder 102. In some embodiments, chip 105 is disposed in an opening 114 of chip holder 102. In some embodiments, chip 105 is connected to a base layer (e.g., a base layer 108 in FIG. 1B) by a die bonding material such as conductive epoxy, sintered Silver, sintered Gold, or eutectic solder. As shown in FIG. 1A, chip holder 102 may include a conductive layer 106 that functions as a circuit surrounding and electrically connected to chip 105 by Gold bonding wires. One or more metal leads 104 may be welded onto chip holder 102, e.g., on opposite sides of chip 105, to be in contact with the circuit. A connecting structure 103 may be in contact with metal leads 104 on each of the opposite sides of the circuit during assembly of this device. In some embodiments, metal leads 104 may be part of the respective connecting structure 103. In some embodiments, metal leads 104 and connecting structures 103 may each include a suitable metallic material such as copper, aluminum, tungsten, aluminum-copper, or a combination thereof. Metal leads may be placed along all four sides (e.g., one to four sides) of the chip as the application requires.

FIG. 1B illustrates a detailed top view of chip holder 102, according to some embodiments. FIG. 1C illustrates a cross-sectional view of chip holder 102 along the A-A direction. For ease of illustration, FIGS. 1B and 1C are described together. Chip holder 102 may include a base layer 108, an insulating layer 110 on base layer 108, conductive layer 106 on insulating layer 110, and a solder mask 124 over conductive layer 106 and insulating layer 110. Base 108 may provide support for a chip (e.g., chip 105), and may include a suitable material of sufficiently low dielectric constant. Base layer 108 may provide a ground (“GND”) for chip 105. For example, base layer 108 may include a suitable metal, such as copper, which is electrically grounded. In some embodiments, a thickness of base layer 108 (e.g., in the z-direction) is between about 200 μm and about 1000 μm. Base layer 108 can have any suitable shape depending on design needs, such as a squared shape, a rectangular shape, or an irregular shape.

Solder mask 124, in contact with conductive layer 106 and insulating layer 110, may surround chip 105 and part of conductive layer 106. Solder mask 124 may divide conductive layer 106 (or chip holder 102 or the conductive pattern) into an inner portion (e.g., surrounded by solder mask 124) and an outer portion (e.g., outside solder mask 124). Solder mask 124 may provide contact for a lid (not shown) that covers chip 105 and the inner portion of conductive layer 106 to seal/prevent chip 105 and the inner portion of conductive layer 106 from contamination such as air and moisture. This solder mask is positioned next to the welded leads, to act as solder stop when the leads are soldered onto the conductive pattern instead of welding. Solder mask 124 may include a suitable insulating material such as epoxy.

In some embodiments, chip holder 102 (e.g., base layer 108) includes various machined patterns 118 for mounting/assembling chip holder 102 (or integrated packaging device 100) onto another device (e.g., a mother board or a heatsink by screws and/or nuts and/or bolts). In some embodiments, machined patterns 118 may include a drilled pattern, e.g., a through hole, on base layer 108. For example, machined patterns 118 include a through hole at each corner of base layer 108. The through hole may have no contact with conductive layer 106.

Insulating layer 110 may be disposed over and in contact (e.g., in direct contact) with base layer 108. Insulating layer 110 may be attached/glued to base layer 108. Insulating layer 110 may provide insulating between conductive layer 106 and base layer 108, and between traces of the conductive pattern of conductive layer 106. For example, insulating layer 110 may be disposed between traces of the conductive pattern of conductive layer 106. Insulating layer 110 may include a pattern that exposes opening 114 and certain other areas of base layer 108. For example, insulating layer 110 may include an opening 112 that completely surrounds opening 114. The size of opening 112 may be equal to or greater than opening 114 such that the vertical projection of opening 114 is completely within the vertical projection of opening 112. In an example, the boundary of opening 112 is desirably close the boundary of opening 114 on the side of wire bonding (e.g., in the x-direction). For example, opening 112 may include a recess portion on the boundary of the wire bonding such that the conductive pattern (e.g., circuit) of conductive layer 106 can be desirably close to chip 105. As shown in FIG. 1B, signal line 120 may be closer to opening 114 than ground lines 122, in the x-direction. For example, a distance (e.g., in the x-direction) between the boundary of opening 114 and the boundary of opening 112 on the side of wire bonding is between about 10 μm and about 50 μm. Insulating layer 110 may also expose certain areas of base layer 108 for electrical/mechanical connections, such as machined pattens 118. In some embodiments, a thickness of insulating layer 110 is between about 200 μm and about 300 μm. Insulating layer 110 may include a suitable insulating material such as a dielectric material (e.g., polytetrafluoroethylene or PTFE) and/or resin. In some embodiments, insulating layer 110 include epoxy.

Conductive layer 106 may be disposed on (e.g., in direct contact with) insulating layer 110. Conductive layer 106 may have a conductive pattern that surrounds opening 114. The conductive pattern may include an opening 113 that aligns/matches with opening 112 of insulating layer 110. For example, boundaries of opening 113 are completely aligned with boundaries of opening 112 by machining both these openings in the same machining setup. The conductive pattern may function as a circuit that connects chip 105 and an external circuitry. The conductive pattern may include a plurality of traces, functioning as one or more lines for conducting electricity. In some embodiments, conductive layer 106 has a thickness between about 10 μm and about 50 μm. Conductive layer 106 may include an inner portion disposed inside solder mask 124 (e.g., in the area enclosed by solder mask 124) and an outer portion outside solder mask 124. For example, conductive layer 106 may include a signal line 120 (e.g., a trace) that extends from the edge of opening 114 to the edge of conductive layer 106. Signal line 120 may be electrically connected to the chip via wire bonding (not shown). Signal line 120 may transmit electrical signals between the chip and an external circuitry. Conductive layer 106 may also include one or more ground lines 122 adjacent to signal line 120, and extending from the edge of opening 114 to the edge of conductive layer 106. Chip holder 102 may include one or more conductive vias 116 extending from ground lines 122 to base layer 108 such that each ground line 122 is electrically connected to base layer 108. In some embodiments, conductive vias 116 are in contact with the common ground (“GND”) formed by the base layer 108. Conductive layer 106 may include a layer of copper. In some embodiments, conductive layer 106 may include a layer of gold on a layer of copper in the inner and outer portions, and include a layer of copper in the area (e.g., between the inner and outer portions) covered by solder mask 124. For ease of illustration, only part of metal leads 104 are shown in FIG. 1B. Metal leads 104 may be in contact with the outer portion of conductive layer 106 by welding. For example, metal leads 104 are welded onto signal line 120 and ground lines 122. Metal leads 104 may be flat or formed into a gullwing. The lengths of metal leads 104 are sufficiently long for connection onto the mother board.

In some embodiments, opening 114 is located at the center of chip holder 102, and extends from the top surface of conductive layer 106 to base layer 108. For example, a bottom surface of opening 114 is located between the top and bottom surfaces of base layer 108. Chip 105 can be bonded onto base layer 108 and wire bonded to conductive layer 106 (e.g., signal line 120 and/or ground lines 122) on the edge of opening 114. As shown in FIGS. 1B and 1D, opening 114 may have a shape that includes a rectangle 107 connected to a protruding portion 109 at each corner of rectangle 107. The size of rectangle 107 can be flexibly designed to fit the size of chip 105. Protruding portion 109 is sufficiently large such that a corner of the chip can be located in. Protruding portion 109 may thus allow the chip to be placed closer to the edge of opening 114 in both the x- and y-directions, and reduce movement of the chip during die mounting. Eutectic die attachment can be improved by the tight tolerances of opening 114. In some embodiments, protruding portion 109 has part of a round shape with a center located at a respective corner of rectangle 107, and has a radius R of between about 25 μm to about 100 μm. Protruding portion 109 may be formed by machining and/or drilling.

As shown in FIG. 1E, opening 114 may extend from the top surface of conductive layer 106 and extend into base layer 108. Opening 114 may have a depth d, equal to the distance between the top surface of chip holder 102 (e.g., the top surface of conductive layer 106) and its bottom surface located between the top and bottom surfaces of base layer 108. Thickness t may at least partially determine the elevation of chip 105 in the z-direction, and affect the wire length for wire bonding. Thus, depth d may be relevant to the impedance between the chip (e.g., 105) and the RF traces. Thickness t of opening 114 may be determined, e.g., at design stage, to match a desirable impedance by varying the length of the bond wires. For example, depth d may be determined to match the impedance between an existing package (e.g., the assembly structure) and the mother board. In some embodiments, depth d is determined based on the total thickness of the chip and the wire length for bonding. For example, a minimum value of t is the sum of thickness of conductive layer 106, insulating layer 110, the thickness of chip 105, and a thickness of the bonding compound on conductive layer 106. Assuming the thickness of conductive layer 106 is about 10 μm, the thickness of insulating layer 110 is about 200 μm, the thickness of chip 105 is about 60 μm, and the thickness of the bonding compound is about 50 μm, the minimum value of t is about 310 μm. In some embodiments, depth d is calculated as the sum of the wire length, the thickness of chip 105, and the thickness of the bonding compound. For example, if the wire length is required to be at least 300 μm in the Z-direction, depth d can be at least 610 μm (e.g., 610-310=300). In various embodiments, depth d can be designed to have various values to match different impedances. In some embodiments, opening 114 may have a depth d ranging between about 310 μm to about 700 μm.

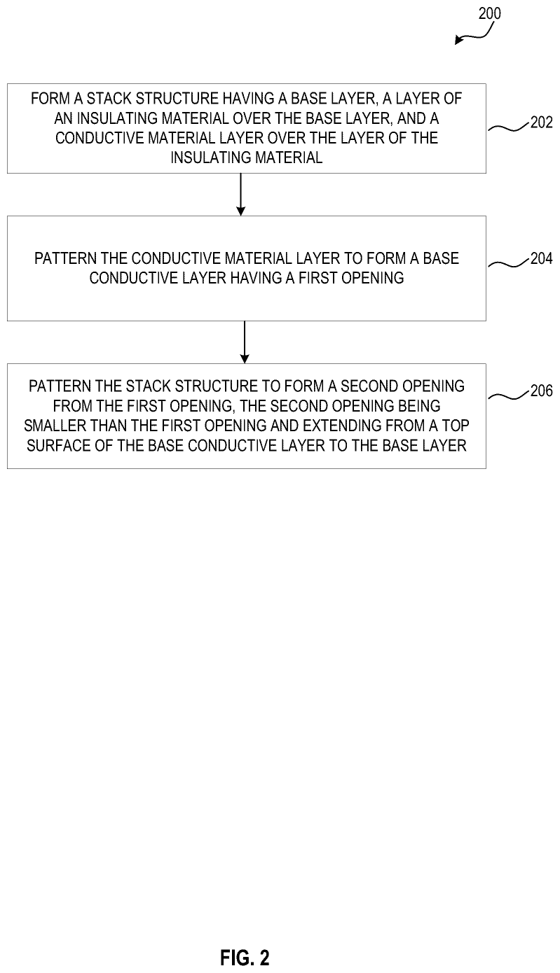

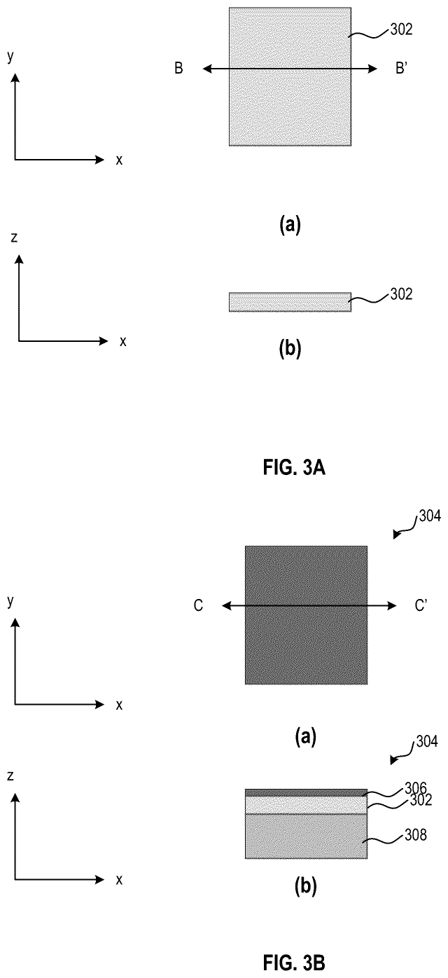

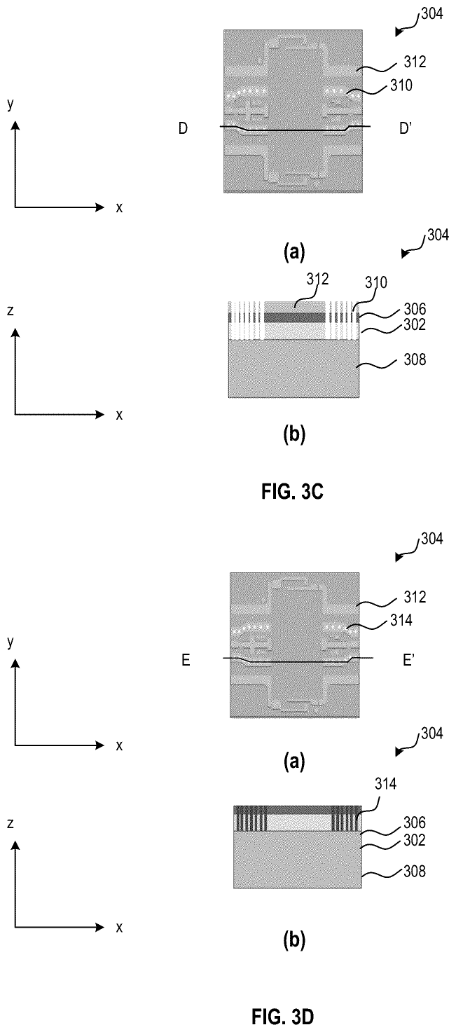

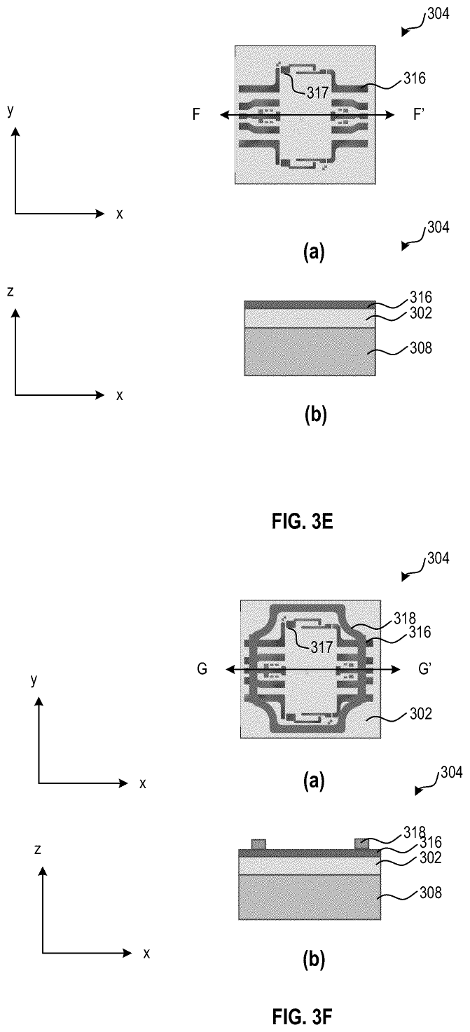

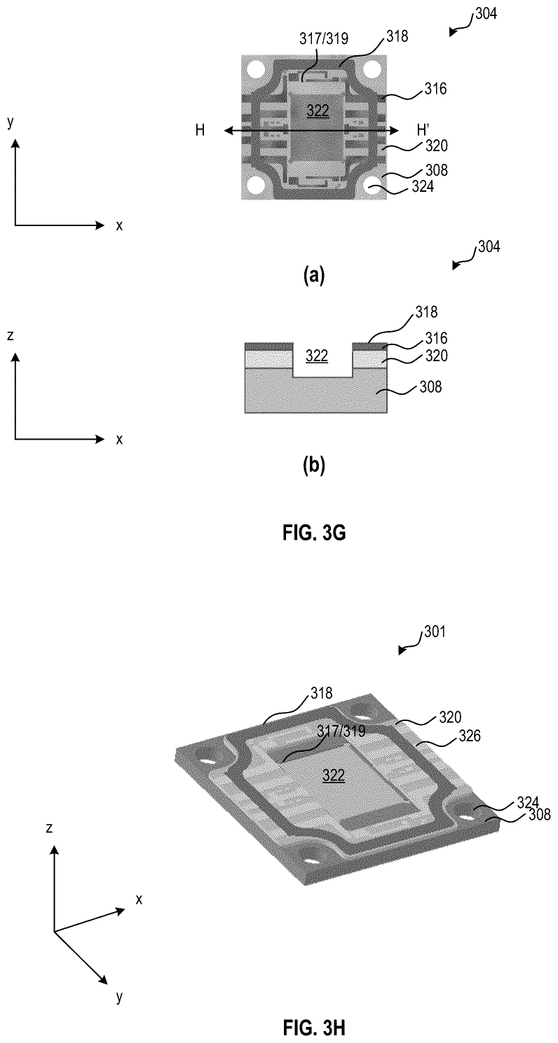

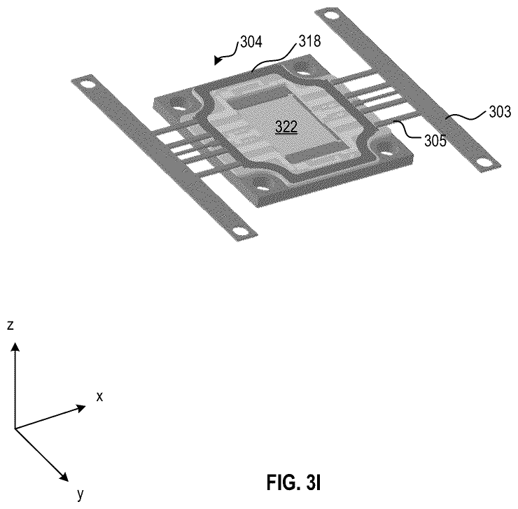

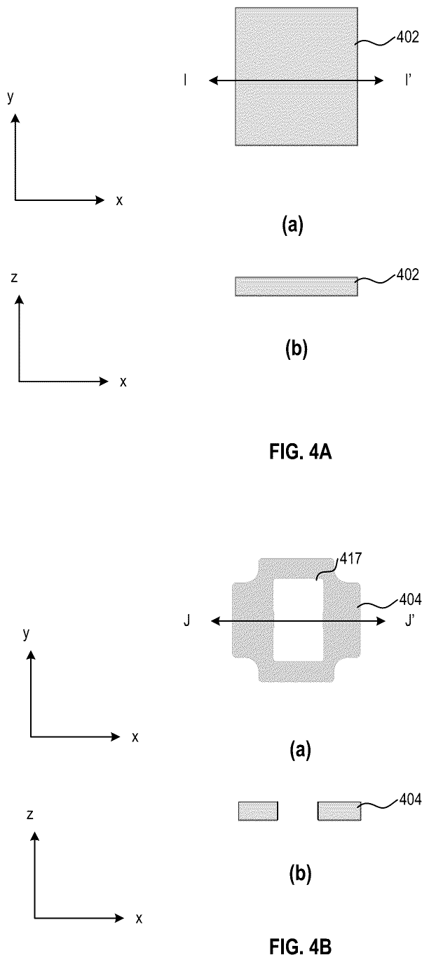

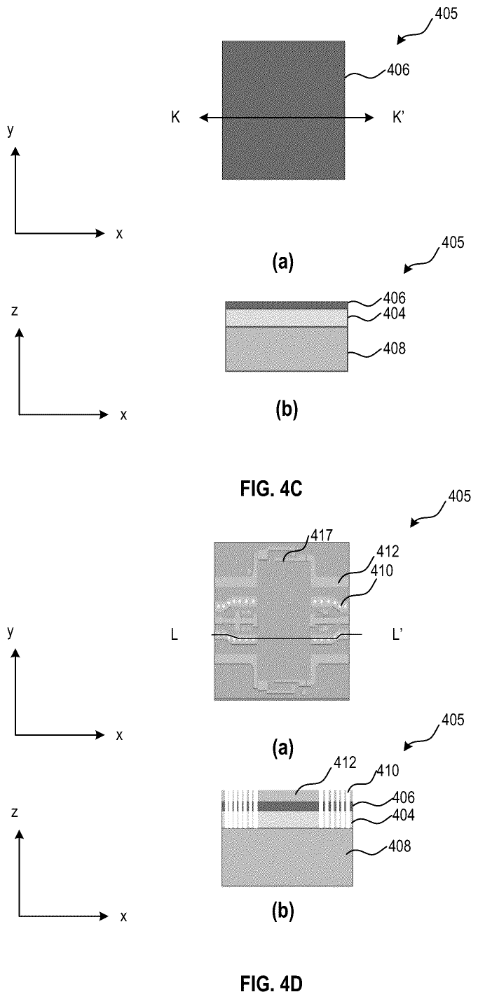

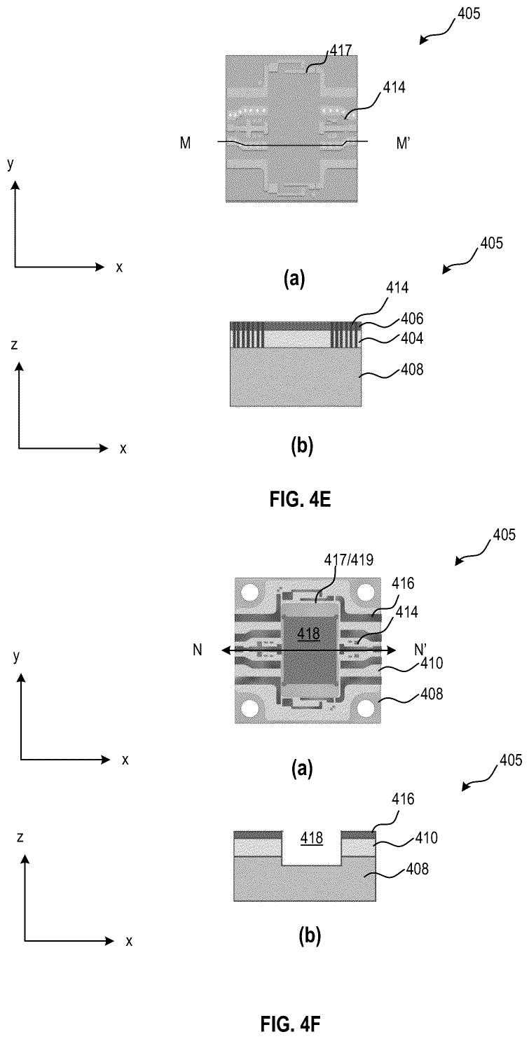

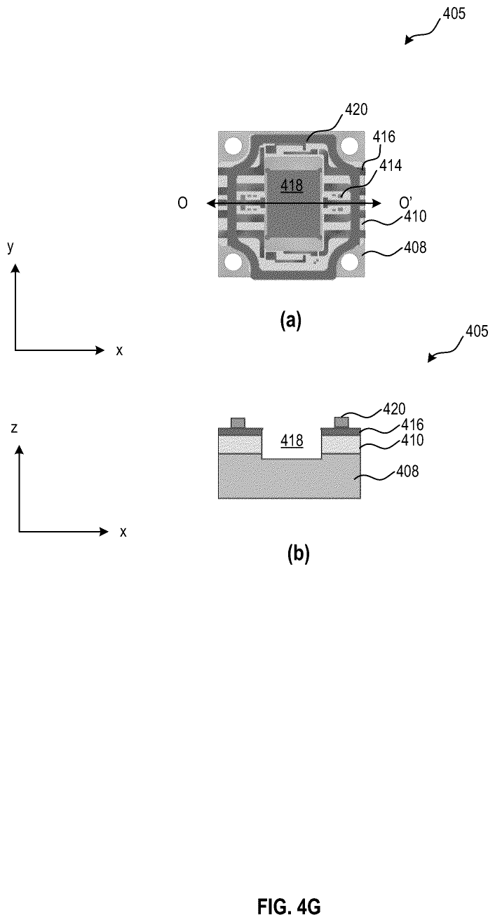

FIG. 2 is a flowchart of a method 200 for fabricating an integrated packaging device, according to some embodiments of the present disclosure. Method 200 is merely an example, and is not intended to limit the present disclosure beyond what is explicitly recited in the claims. Additional operations can be provided before, during, and after the method 200, and some operations described can be replaced, eliminated, or moved around for additional embodiments of method 200. Method 200 will be described in more detail below. FIGS. 3A-3I and 4A-4G illustrate structures of the integrated packing device at different stages of alternative fabrication processes. In FIGS. 3A-3G and 4A-4G, (a) is a top view of the respective structure, and (b) is a cross-sectional view of the respective structure along a respective lateral direction.

At step 202, a stack structure having a base layer, a layer of an insulating material over the base layer, and a conducive material layer over the insulating layer are formed. FIGS. 3A-3D illustrate corresponding structures.

As shown in FIG. 3A, an insulating material layer 302 is provided. In some embodiments, insulating material layer 302 includes low dielectric constant and low loss resin, e.g., PTFE and/or epoxy. A thickness of insulating material layer 302 may be between about 200 μm and about 300 μm.

As shown in FIG. 3B, a stack structure 304 is formed. A conductive material layer 306 and a base layer 308 are provided. Conductive material layer 306 may include a suitable conductive material such as copper, and may have a thickness between about 10 μm and about 50 μm. Base layer 308 may include a suitable material of desirably high thermal conductivity, e.g., metal such as copper. The thickness of base layer 308 may be between about 200 μm and about 1000 μm. Insulating material layer 302 may be disposed between conductive material layer 306 and base layer 308 to form a stack structure 304. In some embodiments, stack structure 304 is formed by laminating (e.g., pressing and
heating) conductive material layer 306, insulating material layer 302, and base layer 308 such that insulating material layer 302 may be directly attached/glued/bonded to conductive material layer 306 and base layer 308 on opposite sides. Stack structure 304 may then be cooled down, e.g., to room temperature.

As shown in FIG. 3C, an etch mask 312 is formed over conductive material layer 306. Etch mask 312, may include any suitable material that can be patterned. For example, etch mask 312 can include a soft mask (e.g., a patterned mylar layer) and/or a hard mask (e.g., chrome pattern on glass). For very fine conductor patterns, a maskless process (direct writing with laser) may also be used. Etch mask 312 may be patterned to expose areas (of stack structure 304) to be removed and cover areas to be retained in the subsequent patterning process. For example, etch mask 312 may expose the area for forming an opening (e.g., similar to 112, 113, and 114) and cover areas for forming a conductive pattern from conductive material layer 306. For example, etch mask 312 may cover areas for forming the ground lines (e.g., similar to 122) and the signal line (e.g., similar to 120) and expose the area between a ground line and the signal line. As shown in FIG. 3C, etch mask 312 may also include a plurality of openings disposed in the area(s) for subsequently forming the ground lines from conductive material layer 306. The openings may each expose part of conductive material layer 306. In some embodiments, etch mask 312 is formed by one or more of a photolithography process, a deposition process (e.g., electrolytic plating, chemical vapor deposition, physical vapor deposition, atomic layer deposition, or the like), and/or an etching process (e.g., dry etch and/or wet etch).

Holes 310 may then be formed in stack structure 304. As shown in FIG. 3C, holes 310 may extend from the top surface of etch mask 312, through conductive material layer 306 to base layer 308. In some embodiments, holes 310 may be in contact with (e.g., expose) metal traces on base layer 108 that corresponding to ground (“GND”). Holes 310 may be formed by a suitable process such as drilling down the openings in etch mask 312, through conductive material layer 306 and insulating material layer 302, until holes 310 expose base layer 308 (or traces of ground on base layer 308).

As shown in FIG. 3D, a plurality of conductive vias 314 are formed in the openings. Conductive vias 314 may extend from the top surface of conductive material layer 306 (or etch mask 312) to base layer 308 such that conductive material layer 306 can be electrically connected to the trace corresponding to ground on base layer 308 through conductive vias 314. In some embodiments, conductive vias 314 include copper and are formed by plating, e.g., electroplating, electroless plating, or a combination thereof. Etch mask 312 may be removed before or after the formation of conductive vias 314. FIG. 3D shows an example in which etch mask 312 is removed before the formation of conductive vias 314.

Referring back to FIG. 2, at step 204, the conductive material layer is patterned to form a base conductive layer having a first opening. FIG. 3E illustrates a corresponding structure.

As shown in FIG. 3E, conductive material layer 306 is patterned, using etch mask 312, to form a base conductive layer 316 over insulating material layer 302. Base conductive layer 316 may have a conductive pattern that includes ground lines and a signal line, and may expose the portion of insulating material layer 302 corresponding to an opening (e.g., similar to 112), e.g., at the center of stack structure 304. In some embodiments, base conductive layer 316 includes an opening 317 (e.g., similar to 113) with a size greater than the opening (e.g., similar to 114) for holding a chip. Opening 317 may expose a portion of insulating material layer 302. Base conductive layer 316 may be formed by a suitable patterning process such as an etching process (e.g., dry etch and/or etch).

As shown in FIG. 3F, a solder mask 318 may be formed and may partially cover base conductive layer 316 and insulating material layer 302. Solder mask 318 may be formed on stack structure 304 through various ways. In an embodiment, solder mask 318 is formed by coating stack structure 304 with a resin layer, and patterning the resin layer. Solder mask 318 may surround the area for forming an opening (e.g., similar to 112), and may divide base conductive layer 316 into an inner portion and an outer portion.

Referring back to FIG. 2, at step 206, the stack structure is patterned to form a second opening extending from the first opening, the second opening being smaller than the first opening and extending from a top surface of the base conductive layer to the base layer. FIG. 3G illustrates a corresponding structure.

As shown in FIG. 3G, stack structure 304 is patterned to form an opening 322 extending from base conductive layer 316 to base layer 308. Insulating material layer 302 may be patterned to form an insulating layer 320 using a suitable etching process such as dry etch and/or wet etch. Insulating layer 320 may expose portions of base layer 308 corresponding to machined patterns for assembly (e.g., similar to 118) and an opening (e.g., similar to 114) for placing a chip. In some embodiments, insulating layer 320 includes an opening 319 that matches/aligns with opening 317. Opening 319 may expose a portion of base layer 308. In some embodiments, insulating layer 320 is patterned using a suitable patterning process such as machining, laser cutting and/or an etching process (dry etch and/or wet etch). After the patterning of insulating material layer 302, stack structure 304 (or base layer 308) may then be patterned to remove portions of base layer 308 to form an opening 322 (e.g., similar to 114) and machined patterns 324. In some embodiments, opening 322 has a shape of a rectangle and one or more protruding portions each at a corner of the rectangle. In some embodiments, opening 322 and machined patterns 324 are formed using one or more of machining and drilling. For example, opening 322 may be formed by machining to a desirable depth in base layer 308 (e.g., similar to base layer 108) for matching impedance (referring back to the description of opening 114 in FIG. 1E).

As shown in FIG. 3H, a gold layer 326 is formed on base conductive layer 316, forming a conductive layer. Gold layer 326 may cover the inner and outer portions of base conductive layer 316. In some embodiments, gold layer 326 is formed by plating, e.g., electroplating and/or electroless plating. Gold layer 326 may make the surface of the conductive layer more suitable for wire bonding and/or die bonding.

As shown in FIG. 3I, metal leads 305 are welded to be in contact with the portion of the conductive layer outside solder mask on two opposite sides of stack structure 304. In some embodiments, each of the ground lines and the signal line is in contact with a metal lead via welding. Metal leads 305 on each side of stack structure 304 may be in contact with (or part of) a connecting structure 303. Connecting structure 303 may include patterns, e.g., through holes, for connecting stack structure 304 (e.g., chip holder 102) with an external circuitry/device. It may be preferred to plate gold after welding, so the leads (303/305), conductors (306/316) and the base (308/324) can be coated with gold in one process step.

FIGS. 4A-4G illustrates structures of a chip holder at different stages of part of an alternative fabrication process, according to some embodiments. For ease of illustration, detailed description of similar or same processes/materials in FIGS. 4A-4G can be referred to those in FIGS. 3A-3G, and is omitted herein.

Referring back to FIG. 2, at step 202, a stack structure having a base layer, a layer of an insulating structure over the base layer, and a conductive material layer over the layer of the insulating material is formed. FIGS. 4A-4C illustrate corresponding structures.

As shown in FIG. 4A, an insulating material layer 402 is provided. Insulating material layer 402 may be similar to insulating material layer 302, and the detailed description is not repeated herein.

As shown in FIG. 4B, insulating material layer 402 may be patterned to form an insulating layer 404. Insulating layer 404 may be patterned form an opening 417 (e.g., similar to 112), e.g., at the center. Opening 417 may have a size larger than that of an opening (e.g., similar to 114) for holding a chip. Insulating layer 404 may also be patterned to have recess areas in the peripheral areas for subsequently forming machined patterns (e.g., similar to 118) in the base layer. The patterning of insulating material layer 402 may include a suitable etching process such as laser cutting, dry etch, and/or wet etch.

As shown in FIG. 4C, insulating layer 404 may be disposed between a conductive material layer 406 and a base layer 408 to form a stack structure 405. Insulating layer 404 may be disposed at a desired location on base layer 408 for subsequent fabrication processes such as patterning conductive material layer 406 and/or base layer 408. For example, insulating layer 404 may be aligned with certain features on base layer 408 before being placed on base layer 408. In some embodiments, conductive material layer 406, insulating layer 404, and base layer 408 may be laminated (e.g., pressed and/or heated) to form stack structure 405.

As shown in FIG. 4D, an etch mask 412 may be formed over conductive material layer 406. Etch mask 412 may correspond to a conductive pattern that functions as a circuit. Similar to etch mask 312, etch mask 412 may include a plurality of openings for forming vias electrically connected to the traces of ground on base layer 408. A plurality of holes 410 are formed by drilling down conductive material layer 406 and insulating layer 404, until holes 410 expose base layer 408 (or traces of ground on base layer 408).

As shown in FIG. 4E, a plurality of conductive vias 414 are formed in holes 410 by plating. The formation of conductive vias 414 is similar to that for conductive vias 314 and the description is not repeated herein.

Referring back to FIG. 2, at step 204, the conductive material layer is patterned to form a base conductive layer having a first opening. FIG. 4F illustrates a corresponding structure.

As shown in FIG. 4F, conductive material layer 406 is patterned to form a base conductive layer 416 over insulating layer 404. Base conductive layer 416 may include an opening 419 that matches/aligns with opening 417 of insulating layer 404. Opening 417 (e.g., and opening 419) may expose a portion of base layer 408 for forming an opening (e.g., similar to 114) that holds a chip. The patterning of conductive material layer 406 may be similar to that of conductive material layer 306, and the detailed description is not repeated herein.

Referring back to FIG. 2, at step 206, the stack structure is patterned to form a second opening from the first opening, the second opening being smaller than the first opening and extending from a top surface of the base conductive layer to the base layer. FIG. 4F illustrates a corresponding structure.

As shown in FIG. 4F, stack structure 405 (e.g., base layer 408) is patterned to form an opening 418 in opening 417/419. Opening 418 may extend from base conductive layer 416 to base layer 408. The formation of opening 418 may be similar to that of opening 322, and the detailed description is not repeated herein.

As shown in FIG. 4G, a solder mask 420 may be disposed onto stack structure 405. The attachment/bonding of solder mask 420 may be similar to that of solder mask 318, and the detailed description is not repeated herein.

After the process shown in FIG. 4G, a gold layer may be plated onto base conductive layer 416 to form a conductive layer, and metal leads may be welded onto part of the conductive layer outside solder mask 420. Detailed description may be referred to the description of FIGS. 3H and 3I, and is not repeated herein.

1. An integrated packaging device, comprising:
a base layer;
an insulating layer over and in contact with the base layer;
a conductive layer over and in contact with the insulating layer, the conductive layer comprising a conductive pattern; and
an opening extending from the conductive layer to the base layer, wherein
the conductive pattern surrounds the opening.

2. The integrated packaging device of claim 1, wherein a bottom surface of the opening is between a top surface and a bottom surface of the base layer.

3. The integrated packaging device of claim 1, wherein the insulating layer comprises epoxy, polytetrafluoroethylene (PTFE).

4. The integrated packaging device of claim 1, wherein:
the opening is configured for placing a circuit chip; and
a depth of the opening is at least a sum of a thickness of the insulating layer, a thickness of the conductive layer, a thickness of the circuit chip, and a thickness of a bonding over the conductive layer.

5. The integrated packaging device of claim 1, wherein:
a thickness of the base layer is between about 200 μm and about 1000 μm;
a thickness of the insulating layer is between about 200 μm and about 300 μm; and
a thickness of the conductive layer is between about 10 μm and about 50 μm.

6. The integrated packaging device of claim 1, wherein the opening comprises a rectangular portion and at least one protruding portion in connection with a corner of the rectangular portion.

7. The integrated packaging device of claim 6, wherein the opening comprises four protruding portions each in connection with a corner of the rectangular portion.

8. The integrated packaging device of claim 1, wherein the base layer and the conductive layer each comprises copper.

9. The integrated packaging device of claim 1, further comprising a plurality of conductive vias connecting a ground line of the conductive pattern and the base layer.

10. The integrated packaging device of claim 1, further comprising:
a mask layer surrounding the opening and separating an inner portion and an outer portion of the conductive pattern; and
a plurality of conductive leads in contact with the outer portion of the conductive pattern.

11. A method for forming an integrated packaging device, comprising:
forming a stack structure comprising a base layer, a layer of an insulating material over the base layer, and a conductive material layer over the layer of the insulating material;
patterning the conductive material layer to form a base conductive layer having a first opening; and
patterning the stack structure to form a second opening from the first opening, the second opening being smaller than the first opening and extending from a top surface of the base conductive layer to the base layer.

12. The method of claim 11, further comprising:
prior to the patterning of the conductive material layer, patterning the stack structure to form a plurality of holes in an area corresponding to a ground line in the base conductive layer, the plurality of holes extending from the conductive material layer to the base layer; and
forming a plurality of conductive vias each in a respective one of the plurality of holes.

13. The method of claim 12, wherein the plurality of conductive vias are formed by electroplating or electroless plating.

14. The method of claim 12, where in the conductive vias comprise copper.

15. The method of claim 11, wherein the forming of the stack structure comprises:
prior to the forming of the stack structure, patterning an insulating material layer to form the layer of the insulating material that has a third opening matching the first opening; and
laminating the base layer, the layer of the insulating material, and the conductive material layer to form the stack structure.

16. The method of claim 15, wherein the laminating of the base layer, the layer of the insulating material, and the conductive material layer comprises applying at least one of heat or pressure on the base layer, the layer of the insulating material, and the conductive material layer such that the layer of the insulating material is attached to each of the conductive material layer and the base layer.

17. The method of claim 15, wherein the patterning of the insulating material layer comprises laser cutting.

18. The method of claim 11, wherein the patterning of the stack structure to form the second opening from the first opening comprises machining the stack structure in the first opening to expose the base layer, the opening having a rectangular portion and at least one protruding portion in connection with a corner of the rectangular portion.

19. The method of claim 18, wherein the opening is formed by machining the layer of the insulating material and the base layer to form the rectangular portion, and machining or drilling the corner of the rectangular portion to form the at least one protruding portion.

20. The method of claim 11, further comprising:
forming a mask layer surrounding the second opening and dividing the base conductive layer into an inner portion and an outer portion;
plating a gold layer covering the inner and outer portions of the base conductive layer to form a conductive layer; and
welding the one or more conductive leads onto the gold layer covering the outer portion of the base conductive layer.
